(19) United States
(12) Patent Application Publication
(10) Pub. No.: US 2002/0145105 A1
(43) Pub. Date: Oct. 10, 2002

(54) Diffractive shadow imaging system

(76) Inventor: Geoffrey B. Rhoads, West Linn, OR (US)

Correspondence Address: William Y. Conwell, Pinecone Imaging Corporation, 6224 SW Tower Way, Portland, OR, 97221, US

(21) Appl. No.: 09/832,316

(22) Filed: Apr. 9, 2001

(51) Int. Cl. H01L 27/00

(52) U.S. Cl. 250/208.1

(57) ABSTRACT

Stars and other celestial sources are sometimes transited by passing objects (e.g., asteroids, comets, and planets) that cast brief and fleeting diffraction shadows across the earth. By sampling light from such events at plural points on the earth's surface, and modeling the intervening diffractive environment, an image of the source can be derived.

Question: How can a coordinated group of amateur astronomers thoroughly and jubilantly blow away the resolving capabilities of the Hubble Space Telescope when they, collectively and in synchrony, image a given brighter celestial object, all while at the same time doing so within a stretched but not improbable budget?

Answer: Diffractive Shadow Imaging.

The explanation of this cryptic question and answer begets another, follow-on cryptic remark: One can now state emphatically to the grade schooler that there is much more than meets the eye in the twinkling in them there stars; look closely and you will see them as you would our own sun!

Drama . . . yes; hyperbole . . . only a hopefully forgivable pinch.

Lunar occultation studies have long been known to offer up certain distant secrets about suns in our local neighborhood. Most notably leading to decent reckonings on their apparent disc sizes and symmetric brightness profiles such as limb darkening plots. This disclosure, searching for the most relevant and direct prior art, offers this as the stable platform for next ascent. Specifically, when the moon eclipses a given distant star, a cadence of diffraction pattern shadows ensue as opposed to the lay expectation of a hard shutter on the starstream, where the capturing of this wave pattern by high speed photodetectors can then be analyzed in order to sleuth the aforementioned details of the size and general demeanor of said eclipsed star. Simple, huh?

Flash from left field, there comes the legend and wished-for present of Polynesians navigating their islands by the subtlelest of interpretations of waves. True? I wish I knew. But in any event, if true, an unequivocal prior art.

Ending whatever suspense has been created here, this disclosure explores two essentially equivalent aspects of Diffractive Shadow Imaging: general, and ecliptic. The latter is subsumed by the former.

What is it? Quite simply, and using the “ecliptic” example as the lead heuristic, its all about using the several million or so solar system bodies, better known as asteroids and comets and planets, as special lenses to view extra-solar system objects. The diffractive shadows of these countless nearby objects, illuminated as they are by the countless of countless supra-solar-system celestial sphere objects, produce a decipherable set of light impinging upon the surface of the planet Earth such that, carefully recorded and coordinated, superior imagery of that celestial sphere can result. Strange but true. On a practical plane relative to the next few decades, the only real limit will be set by cost and sufficient photon flux, two sides of the same coin. The distance of those objects from Earth set the deeper limit.

More technically speaking, any given “normal” telescope camera trained on the celestial sphere is comprised of hundreds of thousands if not millions of pixels effectively sampling that celestial sphere. For the better of high end amateur telescopes, and the typical professional telescope, that pixel-sampling function is idealized as roughly a 5 microradian by 5 microradian sampling function. Atmospheric turbulence as described in vast numbers of works sets the limits on the resolution of these optical sampling functions. Adaptive optics and emplacement of telescopes above the atmosphere, a la Hubble, can push these sampling function limits down to 1 or even 0.1 microradians. Expensive stuff though it may be. Phased radio telescopes and next-generation phased infrared/optical telescopes can push the envelope yet further finer.

So let's instead imagine a given pixel on a normal telescope camera, imaging the celestial sphere on some normal viewing site in the deeper atmospheric soup of the lowlands. 10 by 10 microradians at best, more like 20 by 20 or worse still. Jupiter and Saturn become discernable but disappointing. And we are way way off of resolving the disc of Betegeuse coming in at a scant 250 nanoradians (0.25 microradians).

But now let's imagine a not so uncommon event for celestial sphere objects lying between 10 degrees north and 10 degrees south of the solar ecliptic. It just so happens that millions of objects generally bigger than a football field (as defined by either side of the Atlantic) are routinely sweeping the skies causing ever so subtle ripples in the light waves from distant objects. Their shadows sweep across the face of the Earth typically at speeds between 5 and 20 kilometers per second! Astrophiles such as those in the IOTA [see web site link cited below] spend countless dedicated hours tracking, anticipating and recording the highlight events of the year where the eclipsing asteroids are typically 100's of kilometer's in diameter and starlight is effectively extinguished for a few unearthly seconds in their direct shadows.

And the sampling functions, what of them? Going back to Fresnelian basics, the pixel sampling functions on our “normal” telescope struggling in the soup all of the sudden has this odd but indescribably powerful “dark spot with ripples” that whisks across it in the self same few unearthly seconds. If one coordinates a reasonable bunch of such struggling telescopes, say 50 arrayed across a few tens or hundreds of kilometers in a North/South rough line, and one captures the collective few seconds worth of data (sampled generally at several thousand times per second per pixel), add in that most recent creature called the reasonable cost photon counting array, and add in a diffraction grating in the telescope which spreads the sampling function across the spectrum, and one generates a complete set of data capable of, in general, breaking the nanoradian level of resolution on said celestial sphere. [I.e., a little touch of linear algebra replete with a few crippling massive array inversion and you're there! It'll be easier just to invert the dark spots and make best use of object constraints such as “known discs” to weather the first few years of playtime]. The details of the particular processing operations can be determined by those skilled in the associated arts without undue experimentation.

The contemplated arrangements are eminently practical. Photon starvation (which simply translates to greatly increasing the low-grade optical collection area of the coordinate telescopes) is the chief near term limit on the method. The “dark ripply spot” on the much broader sampling function is indeed subtle and of very low contrast, especially the ripples. As with classic speckle imaging, this translates to the need for lots and lots of data. But the substantial shadows from the substantial distant asteroid scatterers may be numerous but they are extremely fleeting, giving only the aforementioned few seconds worth of useful data. Even so, this is the perfect starting point. May refinements over the decades ensue!

The immediately prior last few paragraphs concentrate on the “ecliptic” special case of DSI. The general case posits that any distant luminous celestial source has between it and us a modelable diffractive environment which, in general, contains no “jackpot” eclipsing bodies but instead a sea of high transparency dust and mini-bodies which nevertheless create subtle diffractive shadows at the surface of the Earth . . . the last few microseconds of atmospheric turbulence absolutely included (but not central to) the general model! The hope here, being that it does not currently lend itself to immediate hard core testing as well as the ecliptic case, is that the general model eventually “eclipses” (I had to do it) the ecliptic model in generic usefulness. But at this writing, it is estimated that this will take some quality time, if not an eternity.

The first subject which comes to the author's mind is to map M31 at 100 picoradian resolution.

To provide a comprehensive disclosure without unduly lengthening this specification, applicant incorporates by reference the disclosure of his prior patents 5,412,200, 5,444,280, 5,448,053, and 6,084,227. Among the disclosures of these references are general processing systems that can be employed to perform the linear algebra and array inversions that may be employed in implementations of the present invention.

A photon counting array suitable as a detector at each of the spaced-apart locations is available from Texas Instruments and is a 2D CCD featuring avalanche circuitry that reduces read noise (e.g., their Single Photon Detection (SPD) line of sensors, such as the TC253). Another alternative is the detector disclosed in my '280 patent. Such arrays can be deployed in terrestrial telescopes as contemplated above, or in orbiting or other space platforms.

Data predicting stellar occultations by asteroids and other objects are available from a number of sources, including the U.S. Naval Observatory (e.g., http://aa.usno.navy.mil/ephemerides/asteroid/astr_alm/asteroid_ephemerides.html), the British Astronomical Society (e.g., http://www.ast.cam.ac.uk/˜baa/occ.html), the European Asteroid Occultation Network (e.g., http://www.xcom.it/cana/EAON/) and the International Occultation Timing Association, or IOTA (e.g., http://www.anomalies.com/iotaweb/index.htm, c/o David Dunham, 23-376, Applied Physics Lab, John Hopkins Rd., Laurel, Md. 20723).

(It should be noted that asteroid occultation of starlight has been used in the prior art to determine the shape of the asteroid. See, e.g., the January, 1992, issue of Sky and Telescope magazine at page 73. But such arrangements are premised on conceptualization of the asteroid as a hard shutter of the starlight, casting a shadow on earth with unambiguous edges, rather than imparting diffracted waves to the light.)

1. In a method of imaging extraterrestrial objects using a system including plural spaced-apart photon receivers and a processing system for processing outputs from said receivers to yield image data, an improvement wherein the method includes collecting photons from an extraterrestrial object as it is being transited or eclipsed by a non-earth body in our solar system, said collecting occurring at said plural receivers.

2. The method of claim 1 that includes generating time-based records of photons received from each of said receivers, each of said records being synchronized to a common reference time base.

3. The method of claim 2 wherein each of said time-based records includes a wave pattern as light from the object is refracted around the non-earth object.

4. The method of claim 3 that includes using said plural time-based records, and the wave patterns therein, in conjunction with information about the relative geographical location of each of the receivers, to synthesize an image of the extraterrestrial object.

5. The method of claim 4 in which the collecting includes collecting with a 2D CCD- or CMOS- photon counting array including avalanche circuitry.

6. A method of imaging a non-terrestrial object comprising collecting diffractive wave patterns from the object, at plural locations, as the object is occluded by a non-Earth body in our solar system.

7. The method of claim 6 in which at least one of said plural locations is on the Earth.

8. The method of claim 6 in which all of said locations are on the Earth.

9. A method of imaging a night star by sampling its twinkling function at plural spaced-apart locations as the star is occluded by an asteroid, comet, or planet.
